(19) United States
(12) Patent Application Publication
(10) Pub. No.: US 2018/0076820 A1
(43) Pub. Date: Mar. 15, 2018

(54) ACCURATE, FINELY TUNABLE ELECTRONIC DELAY GENERATION WITH HIGH PROCESS VARIATION TOLERANCE

(71) Applicant: California Institute of Technology, Pasadena, CA (US)

(72) Inventors: Behrooz Abiri, Alhambra, CA (US); Seyed Ali Hajimiri, La Canada, CA (US)

(21) Appl. No.: 15/701,981

(22) Filed: Sep. 12, 2017

Related U.S. Application Data
(60) Provisional application No. 62/393,500, filed on Sep. 12, 2016.

(51) Int. Cl. H03L 7/081; H03K 5/01

(52) U.S. Cl. CPC H03L 7/0812; H03K 2005/00019; H03K 5/01

(57) ABSTRACT

A delay generation circuit includes a modulator and a delay-locked loop. The delay-locked loop includes a delay line configured to be responsive to a phase difference between a first clock signal and one of a multitude of output signals of the delay line. The delay generation circuit is configured to select one of the multitude of output signals of the delay line in response to the modulator.

### CROSS-REFERENCES TO RELATED APPLICATIONS

This application claims priority, under 35 U.S.C. § 119(e), from U.S. Provisional Application No. 62/393,500, filed on Sep. 12, 2016, entitled “ACCURATE, FINELY TUNABLE ELECTRONIC DELAY GENERATION WITH HIGH PROCESS VARIATION TOLERANCE,” the contents of all of which is incorporated herein by reference in its entirety.

### BACKGROUND

The present disclosure relates generally to a time delay generation circuit.

Variable delay generation is widely used in electronic circuits to adjust the clock timing. In phased array systems such clock timing adjustment is used to control the phase of each element in the array. Two desirable requirements in delay generation of phased array systems is the ability to produce a finely controlled delay with high absolute accuracy.

Therefore, there is a need for producing a variable delay circuit having delay control with high absolute accuracy.

### SUMMARY

According to one embodiment of the present invention, a delay generation circuit includes a modulator and a delay-locked loop. The delay-locked loop includes a delay line configured to be responsive to a phase difference between a first clock signal and one of a multitude of output signals of the delay line. The delay generation circuit is configured to select one of the multitude of output signals of the delay line in response to the modulator.

According to one embodiment, the modulator is a delta sigma modulator. According to one embodiment, the delay generation circuit further includes a multiplexer configured to select the one of the multitude of output signals of the delay line in response to the modulator.

According to one embodiment, the modulator is configured to generate a single bit in response to a multitude of bits received by the modulator. One of the multitude of output signals of the delay line is selected in response to a digital value of the single bit.

According to one embodiment, the delay line includes a multitude of delay elements. The number of delay elements is N. The period of the first clock signal is T. The number of bits received by the modulator is M. The delay generation circuit is configured to provide a delay resolution characterized by the expression T/(2^{M}(N−1)). According to one embodiment, the delay generation circuit is configured to provide a delay in a range between T and TN/(N−1).

According to one embodiment, the one of the multitude of output signals of the delay line is configured to provide a negative feedback to the delay-locked loop. According to one embodiment, the delay-locked loop further includes a phase detector including a negative input and a positive input. One of the multitude of output signals of the delay line is coupled to the negative input and the first clock signal is coupled to the positive input.

According to one embodiment, the delay line includes a multitude of delay elements each configured to be responsive to the phase difference. Each of the multitude of delay elements are serially connected in a sequence. One of the multitude of delay elements connected first in the sequence is configured to receive the first clock signal. One of the multitude of delay elements connected last in the sequence is configured to generate a first one of the multitude of output signals. One of the multitude of delay elements connected before the last in the sequence is configured to generate a second one of the multitude of output signals.

According to one embodiment, the first one of the multitude of output signals is the output of the delay generation circuit. According to one embodiment, each of the multitude of delay elements is configured to be controlled by a voltage that is responsive to the phase difference.

According to one embodiment, the delay-locked loop further includes a phase detector configured to generate the phase difference and a charge pump configured to be responsive to the phase detector. According to one embodiment, the delay-locked loop is configured to increase a voltage generated by the charge pump when the phase detector determines an edge of a selected one of the multitude of output signals of the delay line is occurring before an edge of the first clock signal. According to one embodiment, the delay-locked loop is configured to decrease a voltage generated by the charge pump when the phase detector determines an edge of a selected one of the multitude of output signals of the delay line is occurring after an edge of the first clock signal. According to one embodiment, the edge is a rising edge. According to one embodiment, the edge is a falling edge.

According to one embodiment, the delay-locked loop further includes a low pass filter coupled between the charge pump and the delay line. The low pass filter is configured to remove a noise signal on a voltage generated by the charge pump. The noise signal is responsive to the modulator.

According to one embodiment of the present invention, a method for generating a delay by a delay generation circuit is presented. The method includes coupling a modulator to a delay-locked loop. The delay-locked loop includes a delay line. The method further includes responding to a phase difference between a first clock signal and one of a multitude of output signals of the delay line. The method further includes selecting one of the multitude of output signals of the delay line in response to the modulator.

According to one embodiment, the method further includes configuring a multiplexer to select the one of the multitude of output signals of the delay line in response to the modulator. According to one embodiment, the modulator generates a single bit in response to a multitude of bits received by the modulator. One of the multitude of output signals of the delay line is selected in response to a digital value of the single bit.

According to one embodiment, the delay line includes a multitude of delay elements. The number of delay elements is N. The period of the first clock signal is T. The number of bits received by the modulator is M. The delay generation circuit provides a delay resolution characterized by the expression T/(2^{M}(N−1)). According to one embodiment, the delay generation circuit provides a delay in a range between T and TN/(N−1). According to one embodiment, one of the multitude of output signals of the delay line provides a negative feedback to the delay-locked loop.

According to one embodiment, the delay line includes a multitude of delay elements each responding to the phase difference. Each of the multitude of delay elements are serially connected in a sequence. One of the multitude of delay elements connected first in the sequence receives the first clock signal. One of the multitude of delay elements connected last in the sequence generates a first one of the multitude of output signals. One of the multitude of delay elements connected before the last in the sequence generates a second one of the multitude of output signals.

According to one embodiment, each of the multitude of delay elements is controlled by a voltage that responds to the phase difference. According to one embodiment, the method further includes utilizing the delay generation circuit in a phase array system.

According to one embodiment, the delay-locked loop further includes a phase detector that generates the phase difference, and a charge pump that responds to the phase detector. According to one embodiment, the delay-locked loop increases a voltage generated by the charge pump when the phase detector determines an edge of a selected one of the multitude of output signals of the delay line is occurring before an edge of the first clock signal. According to one embodiment, the delay-locked loop decreases a voltage generated by the charge pump when the phase detector determines an edge of a selected one of the multitude of output signals of the delay line is occurring after an edge of the first clock signal.

According to one embodiment, the delay-locked loop further includes a low pass filter coupled between the charge pump and the delay line. The low pass filter removes a noise signal on a voltage generated by the charge pump. The noise signal responds to the modulator.

A better understanding of the nature and advantages of the embodiments of the present invention may be gained with reference to the following detailed description and the accompanying drawings.

### BRIEF DESCRIPTION OF THE DRAWINGS

FIG. 1 depicts a simplified exemplary block diagram of a variable delay generation circuit, in accordance with one embodiment of the present invention.

FIG. 2 depicts a simplified exemplary timing diagram for the variable delay generator previously depicted in FIG. 1, in accordance with one embodiment of the present invention.

FIG. 3 depicts a simplified exemplary block diagram of a phased array antennae system controlled in part by a multitude of variable delay generators previously depicted in FIG. 1, in accordance with one embodiment of the present invention.

### DETAILED DESCRIPTION

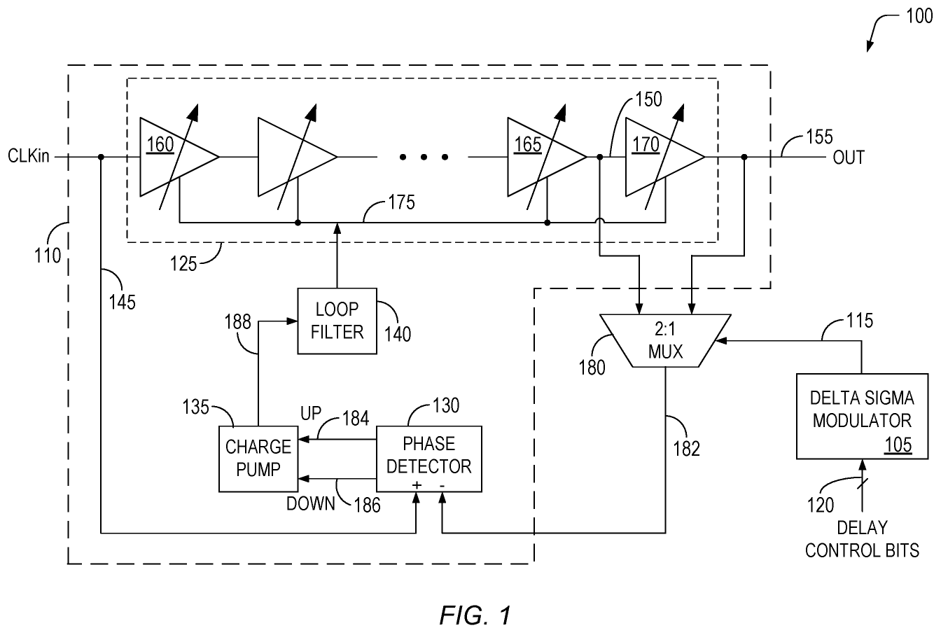

FIG. 1 depicts a simplified exemplary block diagram of a variable delay generation circuit 100, in accordance with one embodiment of the present invention. Variable delay generation circuit 100 includes a modulator 105, and a delay-locked loop 110. In one preferred embodiment, modulator 105 may be a delta sigma modulator to provide high absolute accuracy. In other less accurate embodiments, modulator 105 may be a pulse width modulator (PWM), or other type of modulator. Modulator 105 is configured to generate a single bit at signal 115 in response to a multitude of delay control bits 120 received by modulator 105. In other words, modulator 105 converts the high resolution delay commands to one bit.

A delta sigma modulator is widely used in audio applications where a very linear and accurate digital to analog converter (DAC) is required. This type of linear and accurate DAC converts a low frequency, high resolution digital word into a lower resolution, higher frequency digital code. In the extreme case, the lower resolution code is only one bit. This allows for very linear DAC realization. In this case modulator 105 can be thought of as a block that produces a rapidly changing bit at signal 115 that, on average, is equal to the higher resolution command at the multitude of delay control bits 120.

Delay-locked loop 110 includes a variable delay line 125, a phase detector 130, a charge pump 135, and a low pass loop filter 140. Variable delay line 125 is configured to be responsive to a phase difference between a clock signal CLKin 145 and one of a multitude of output signals 150, 155 of variable delay line 125. Variable delay generation circuit 100 is configured to select one of the multitude of output signals 150, 155 of variable delay line 125 in response to modulator 105.

Variable delay line 125 includes a multitude of adjustable delay elements 160, 165, 170 each configured to be responsive to the phase difference. Each of the multitude of adjustable delay elements 160, 165, 170 are serially connected in a sequence or cascaded. One of the multitude of adjustable delay elements 160 is connected first in the sequence and is configured to receive clock signal CLKin 145. One of the multitude of adjustable delay elements 170 is connected last in the sequence and is configured to generate one of the multitude of output signals 155, i.e. the N^{th} delay element output signal when the number of adjustable delay elements 160, 165, 170 is N. In one embodiment, one of the multitude of output signals 155 of variable delay line 125 is also the output of variable delay generation circuit 100.

One of the multitude of adjustable delay elements 165 connected before the last in the sequence is configured to generate another one of the multitude of output signals 150. It is understood that one of the multitude of output signals 150, 155 of variable delay line 125 that are selected may be generated from immediately adjacent or non-adjacent ones of the multitude of adjustable delay elements 160, 165, 170. In one embodiment, the signal delay generated by each of the multitude of adjustable delay elements 160, 165, 170 is configured to be controlled by a voltage on signal 175 that is responsive to the phase difference.

Variable delay generation circuit 100 further includes a multiplexer 180 configured to select one of the multitude of output signals 150, 155 of variable delay line 125 in response to modulator 105. One of the multitude of output signals 150, 155 of variable delay line 125 is selected in response to a digital value of the single bit generated by modulator 105. In one embodiment, multiplexer 180 may be a 2:1 multiplexer or any other circuit including the same function as a 2:1 multiplexer.

One of the multitude of output signals 150, 155 of variable delay line 125 is configured to provide a negative feedback to delay-locked loop 110. Phase detector 130 includes a negative input and a positive input. One of the multitude of output signals 150, 155 of variable delay line 125 selected by multiplexer 180 is coupled on signal 182 to the negative input of phase detector 130 and clock signal CLKin 145 is coupled to the positive input of phase detector 130. Phase detector 130 is configured to generate the phase difference output on an up signal 184 and a down signal 186.

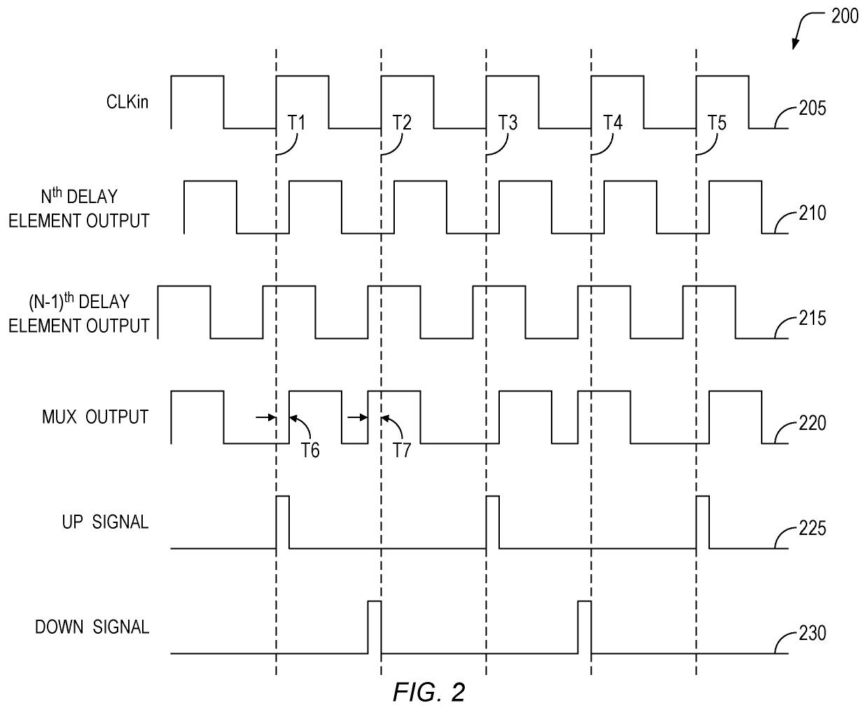

FIG. 2 depicts a simplified exemplary timing diagram 200 for variable delay generator 100 previously depicted in FIG. 1, in accordance with one embodiment of the present invention. Referring simultaneously to FIG. 1 and FIG. 2, timing diagram 200 depicts clock signal CLKin 145 is represented on waveform 205, which includes a rising edge transition at times T0, T2, T3, T4, T5. One of the multitude of output signals 155, i.e. the N^{th} delay element output signal when the number of adjustable delay elements 160, 165, 170 is N, is represented by waveform 210. One of the multitude of output signals 150, i.e. the (N−1)^{th} delay element output signal when the number of adjustable delay elements 160, 165, 170 is N, is represented by waveform 215. The output of multiplexer 180 is represented by waveform 220, which during any clock period selects either waveform 210 or waveform 215 depending on the state of the single bit at signal 115. Up signal 184 is represented by waveform 225. Down signal 186 is represented by waveform 230.

At the rising edge of clock signal CLKin 145, whenever the output of multiplexer 180 is at a logic low the phase difference detected by phase detector 130 is positive, e.g. because the selected one of the multitude of output signals is output signal 155 having a rising edge closest to and occurring after the rising edge of clock signal CLKin 145, such as during time T6. When the phase difference is positive, phase detector 130 generates a pulse on up signal 184, as depicted at times T1, T3, T5 on waveform 225, while no pulse is generated on down signal 186, as depicted on waveform 230.

At the rising edge of clock signal CLKin 145, whenever the output of multiplexer 180 is at a logic high, the phase difference detected by phase detector 130 is negative, e.g. because the selected one of the multitude of output signals is output signal 150 having a rising edge closest to and occurring before the rising edge of clock signal CLKin 145, such as during time T7. When the phase difference is negative, phase detector 130 generates a pulse on down signal 186, as depicted just before times T2, T4 on waveform 230, while no pulse is generated on up signal 184, as depicted on waveform 225.

Charge pump 135 is configured to be responsive to phase detector 130 because charge pump 135 receives up signal 184 and down signal 186. Charge pump 135 generates a voltage that increments when a pulse on up signal 184 is received and that decrements when a pulse on down signal 186 is received. Accordingly, delay-locked loop 110 is configured to increase the voltage on a signal 188 generated by charge pump 135 when phase detector 130 determines a rising edge of a selected one of the multitude of output signals 150, 155 of variable delay line 125 is occurring ahead of or before a rising edge of clock signal CLKin 145. Delay-locked loop 110 is further configured to decrease the voltage on signal 188 generated by charge pump 135 when phase detector 130 determines a rising edge of a selected one of the multitude of output signals 150, 155 of variable delay line 125 is occurring after a rising edge of clock signal CLKin 145.

Delay-locked loop further includes low pass loop filter 140 coupled between charge pump 135 and variable delay line 125. Low pass loop filter 140 is configured to remove a noise signal on the voltage on signal 188 generated by charge pump 135. The noise signal is responsive to modulator 105. Modulators, such as delta sigma modulators, produce strong high frequency noise that should be filtered out from the actual signal that resides at lower frequencies.

Modulator 105 continuously switches multiplexer 180 via signal 115 in response to the multitude of delay control bits 120, which are relatively static compared to clock signal CLKin 145. In-turn, phase detector 130 produces pulses on up signal 184 and down signal 186 based on the selected delay output as represented in waveform 225 and waveform 230, respectively. The pulses on up signal 184 and down signal 186 contain the high frequency noise of Modulator 105. The high frequency noise of Modulator 105 is filtered by charge pump 135 and low pass loop filter 140 to produce the voltage on signal 175 that controls the multitude of adjustable delay elements 160, 165, 170.

When the digital values of the multitude of delay control bits 120 is changed, then over a constant number of cycles of clock signal CLKin 145, the up/down pulse ratio of the number of pulses on up signal 184 to the number of pulses on down signal 186 will initially not be equal. As a result, the voltage at signal 188 and signal 175 starts to change. Due to the negative feedback of variable delay generation circuit 100, the delay of each of the multitude of adjustable delay elements 160, 165, 170 changes until the up/down pulse ratio becomes unity again and the voltage control on signal 188 and signal 175 stabilizes. The amount of delay change in the multitude of adjustable delay elements 160, 165, 170 is linearly related to the digital values of the multitude of delay control bits 120.

When the digital values of the multitude of delay control bits 120 is set to 0, the single bit output of modulator 105 will be logical zero. Accordingly, the number of the multitude of adjustable delay elements 160, 165, 170 in delay-locked loop 110 is reduced to only N−1. Then, the delay of each of the multitude of adjustable delay elements 160, 165, 170 will be T/(N−1) where the period of clock signal CLKin 145 is T.

When the digital values of the multitude of delay control bits 120 are all set to 1 or their maximum value, the single bit output of modulator 105 will be logical one. Accordingly, the number of the multitude of adjustable delay elements 160, 165, 170 in delay-locked loop 110 is reduced to only N. Then, the delay of each of the multitude of adjustable delay elements 160, 165, 170 will be T/N. Accordingly, variable delay generation circuit 100 is configured to provide a delay D in a range given by equation 1.

$$T < D < \frac{N}{( N - 1 )} T . \qquad eq . 1 )$$

Accordingly, when the number of delay control bits 120 received by modulator 105 is M, then variable delay generation circuit 100 is configured to provide a delay resolution R characterized by the expression in equation 2. It should be noted that the linearity of the phase delay directly depends on the linearity of the feedback block including phase detector 130, charge pump 135 and low pass loop filter 140.

$$R = \frac{T}{{2}^{M} ( N - 1 )} . \qquad eq . 2 )$$

According to one embodiment of the present invention, a method for generating a delay by variable delay generation circuit 100 is presented. The method includes coupling modulator 105 to delay-locked loop 110. The method further includes responding to a phase difference between clock signal CLKin 145 and one of a multitude of output signals 150, 155 of variable delay line 125. The method further includes selecting one of the multitude of output signals 150, 155 of variable delay line 125 in response to modulator 105.

According to one embodiment, the method further includes configuring multiplexer 180 to select one of the multitude of output signals 150, 155 of variable delay line 125 in response to modulator 105. According to one embodiment, modulator 105 generates a single bit on signal 115 in response to the multitude of delay control bits 120 received by modulator 105. One of the multitude of output signals 150, 155 of variable delay line 125 is selected in response to a digital value of the single bit.

According to one embodiment, variable delay generation circuit 100 provides a delay resolution characterized by the expression T/(2^{M}(N−1)). According to one embodiment, variable delay generation circuit 100 provides a delay in a range between T and TN/(N−1). According to one embodiment, one of the multitude of output signals 150, 155 of variable delay line 125 provides a negative feedback to delay-locked loop 110.

According to one embodiment, each of the multitude of adjustable delay elements 160, 165, 170 are serially connected in a sequence. One of the multitude of adjustable delay elements 160, 165, 170 connected first in the sequence receives clock signal CLKin 145. One of the multitude of adjustable delay elements 160, 165, 170 connected last in the sequence generates a first one of the multitude of output signals 150, 155. One of the multitude of adjustable delay elements 160, 165, 170 connected before the last in the sequence generates a second one of the multitude of output signals 150, 155.

According to one embodiment, each of the multitude of adjustable delay elements 160, 165, 170 is controlled by a voltage that responds to the phase difference. According to one embodiment, the method further includes utilizing variable delay generation circuit 100 in a phase array system 300.

According to one embodiment, phase detector 130 generates the phase difference, and charge pump 135 responds to phase detector 130. According to one embodiment, delay-locked loop 110 increases a voltage generated by charge pump 135 when phase detector 130 determines a riding edge of a selected one of the multitude of output signals 150, 155 of variable delay line 125 is occurring before a rising edge of clock signal CLKin 145. According to one embodiment, delay-locked loop 110 decreases a voltage generated by charge pump 135 when phase detector 130 determines a rising edge of a selected one of the multitude of output signals 150, 155 of variable delay line 125 is occurring after a rising edge of clock signal CLKin 145.

According to one embodiment, low pass loop filter 140 removes a noise signal on a voltage generated by charge pump 135. The noise signal responds to modulator 105.

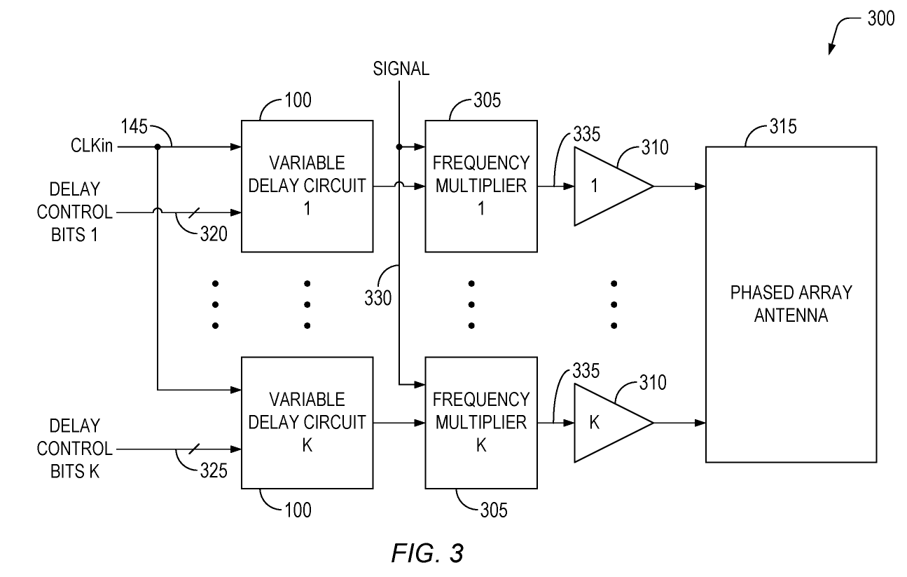

FIG. 3 depicts a simplified exemplary block diagram of a phased array antennae system 300 controlled in part by a multitude of variable delay generators 100 previously depicted in FIG. 1, in accordance with one embodiment of the present invention. Delay generation circuit 100 may be utilized in a phase array system. Phased array antennae system 300 may include, in-part, a multitude of delay generation circuits 100, a multitude of frequency multipliers 305, a multitude of amplifiers 310, and a phased array antennae 315. Each of the multitude of frequency multipliers 305 may include a phase-locked loop. Each of the multitude of delay generation circuits 100 may receive clock signal CLKin 145 and a different one of a multitude of delay control bits 320, 325.

An output of each of the multitude of delay generation circuits 100 is serially coupled through a different one of the multitude of frequency multipliers 305 and through a different one of the multitude of amplifiers 310, which in-turn drive K different ones of a multitude of antennae elements included in phased array antennae 315. A signal 330 having lower frequency than clock signal CLKin 145 may be coupled to each of the multitude of frequency multipliers 305 and multiplied with the different outputs of each of the multitude of delay generation circuits 100 to generate a multitude of multiplied signals 335. Each of the multitude of multiplied signals 335 is associated with a corresponding one of the multitude of delay generation circuits 100, each controlled via the corresponding multitude of delay control bits 320, 325. Each of the multitude of multiplied signals 335 is separately amplified and coupled to each of the K different ones of the multitude of antenna in phased array antennae 315. Accordingly, the direction and power of the signal radiated from phased array antennae 315 may be controlled by the precisely controlled different phase delays enabled by the multitude of delay generation circuits 100.

The above descriptions of embodiments of the present invention are illustrative and not limitative. Although, the invention has been described with reference to an exemplary multiplexor by way of an example, it is understood that the invention is not limited by the type of multiplexer. Although, the invention has been described with reference to an exemplary modulator by way of an example, it is understood that the invention is not limited by the type of modulator. Other modifications and variations will be apparent to those skilled in the art and are intended to fall within the scope of the appended claims.

What is claimed is:

1. A delay generation circuit comprising:
a modulator; and
a delay-locked loop including a delay line configured to be responsive to a phase difference between a first clock signal and one of a plurality of output signals of the delay line, wherein the delay generation circuit is configured to select one of the plurality of output signals of the delay line in response to the modulator.

2. The delay generation circuit of claim 1, wherein the modulator is a delta sigma modulator.

3. The delay generation circuit of claim 1 further comprising a multiplexer configured to select the one of the plurality of output signals of the delay line in response to the modulator.

4. The delay generation circuit of claim 1, wherein the modulator is configured to generate a single bit in response to a plurality of bits received by the modulator, wherein the one of the plurality of output signals of the delay line is selected in response to a digital value of the single bit.

5. The delay generation circuit of claim 4, wherein the delay line comprises a plurality of delay elements, wherein the number of delay elements is N, wherein the period of the first clock signal is T, wherein the number of bits received by the modulator is M, wherein the delay generation circuit is configured to provide a delay resolution characterized by the expression T/(2^{M}(N−1)).

6. The delay generation circuit of claim 1, wherein the one of the plurality of output signals of the delay line is configured to provide a negative feedback to the delay-locked loop.

7. The delay generation circuit of claim 1, wherein the delay-locked loop further includes a phase detector including a negative input and a positive input, wherein the one of the plurality of output signals of the delay line is coupled to the negative input and the first clock signal is coupled to the positive input.

8. The delay generation circuit of claim 1, wherein the delay line comprises:
a plurality of delay elements each configured to be responsive to the phase difference, wherein each of the plurality of delay elements are serially connected in a sequence, wherein the one of the plurality of delay elements connected first in the sequence is configured to receive the first clock signal, wherein the one of the plurality of delay elements connected last in the sequence is configured to generate a first one of the plurality of output signals, wherein the one of the plurality of delay elements connected before the last in the sequence is configured to generate a second one of the plurality of output signals.

9. The delay generation circuit of claim 8, wherein the first one of the plurality of output signals is the output of the delay generation circuit.

10. The delay generation circuit of claim 8, wherein each of the plurality of delay elements is configured to be controlled by a voltage that is responsive to the phase difference.

11. The delay generation circuit of claim 1, wherein the delay-locked loop further includes:
a phase detector configured to generate the phase difference; and
a charge pump configured to be responsive to the phase detector.

12. The delay generation circuit of claim 11, wherein the delay-locked loop is configured to increase a voltage generated by the charge pump when the phase detector determines an edge of a selected one of the plurality of output signals of the delay line is occurring before an edge of the first clock signal.

13. The delay generation circuit of claim 11, wherein the delay-locked loop is configured to decrease a voltage generated by the charge pump when the phase detector determines an edge of a selected one of the plurality of output signals of the delay line is occurring after an edge of the first clock signal.

14. The delay generation circuit of claim 11, wherein the delay-locked loop further includes:
a low pass filter coupled between the charge pump and the delay line, wherein the low pass filter is configured to remove a noise signal on a voltage generated by the charge pump, wherein the noise signal is responsive to the modulator.

15. A method for generating a delay by a delay generation circuit, the method comprising:
coupling a modulator to a delay-locked loop, wherein the delay-locked loop includes a delay line;
responding to a phase difference between a first clock signal and one of a plurality of output signals of the delay line; and
selecting one of the plurality of output signals of the delay line in response to the modulator.

16. The method of claim 15, wherein the modulator is a delta sigma modulator.

17. The method of claim 15 further comprising configuring a multiplexer to select the one of the plurality of output signals of the delay line in response to the modulator.

18. The method of claim 15, wherein the modulator generates a single bit in response to a plurality of bits received by the modulator, wherein the one of the plurality of output signals of the delay line is selected in response to a digital value of the single bit.

19. The method of claim 18, wherein the delay line comprises a plurality of delay elements, wherein the number of delay elements is N, wherein the period of the first clock signal is T, wherein the number of bits received by the modulator is M, wherein the delay generation circuit provides a delay resolution characterized by the expression T/(2^{M}(N−1)).

20. The method of claim 15, wherein the one of the plurality of output signals of the delay line provides a negative feedback to the delay-locked loop.

21. The method of claim 15, wherein the delay-locked loop further includes a phase detector including a negative input and a positive input, wherein the one of the plurality of output signals of the delay line is coupled to the negative input and the first clock signal is coupled to the positive input.

22. The method of claim 15, wherein the delay line comprises:
a plurality of delay elements each responding to the phase difference, wherein each of the plurality of delay elements are serially connected in a sequence, wherein the one of the plurality of delay elements connected first in the sequence receives the first clock signal, wherein the one of the plurality of delay elements connected last in the sequence generates a first one of the plurality of output signals, wherein the one of the plurality of delay elements connected before the last in the sequence generates a second one of the plurality of output signals.

23. The method of claim 22, wherein the first one of the plurality of output signals is the output of the delay generation circuit.

24. The method of claim 22, wherein each of the plurality of delay elements is controlled by a voltage that responds to the phase difference.

25. The method of claim 15 further comprising utilizing the delay generation circuit in a phase array system.

26. The method of claim 15, wherein the delay-locked loop further includes:
a phase detector that generates the phase difference; and
a charge pump that responds to the phase detector, wherein the delay-locked loop increases a voltage generated by the charge pump when the phase detector determines an edge of a selected one of the plurality of output signals of the delay line is occurring before an edge of the first clock signal.

27. The method of claim 15, wherein the delay-locked loop further includes:
a phase detector that generates the phase difference; and
a charge pump that responds to the phase detector, wherein the delay-locked loop decreases a voltage generated by the charge pump when the phase detector determines an edge of a selected one of the plurality of output signals of the delay line is occurring after an edge of the first clock signal.

28. The method of claim 15, wherein the delay-locked loop further includes:
a phase detector that generates the phase difference; and
a charge pump that responds to the phase detector, wherein the delay-locked loop further includes a low pass filter coupled between the charge pump and the delay line, wherein the low pass filter removes a noise signal on a voltage generated by the charge pump, wherein the noise signal responds to the modulator.
